(19) United States
(12) Patent Application Publication
(10) Pub. No.: US 2005/0110112 A1
(43) Pub. Date: May 26, 2005

(54) Encapsulated chip and procedure for its manufacture

(76) Inventor: Wolfgang Ramin, Freising (DE)

Correspondence Address: TEXAS INSTRUMENTS INCORPORATED, P O BOX 655474, M/S 3999, DALLAS, TX, 75265, US

(21) Appl. No.: 11/025,245

(22) Filed: Dec. 28, 2004

Related U.S. Application Data
(62) Division of application No. 10/629,095, filed on Jul. 29, 2003.

(30) Foreign Application Priority Data
Aug. 5, 2002 (DE) 102 35 771.4

(51) Int. Cl. H01L 29/00

(52) U.S. Cl. 257/529

(57) ABSTRACT

An encapsulated chip chip 10 is attached to a baseplate 12, a conductive layer 14 that is at least as high as the chip 10 is attached to the baseplate. A cover plate 16, provided with electrically conductive surfaces 18, is arranged on this conductive layer 14, which is both electrically and mechanically connected with the chip 10 and the conductive layer 14, for example by means of an anisotropically conductive film 26. The cover plate 16 offers protection against touch contact and other mechanical influences. The anisotropically conductive film 26 completely encloses the chip 10. The cover plate 16 provides an electrical connection between the chip 10 and the conductive layer 14 and, at the same time, serves as encapsulation for the chip 10. Because of this, manufacture of the chip 10 becomes easy and cost-effective and only requires relatively few process steps. Because the conductive layer 14 is as high as the chip 10, or is higher than the chip 10, the chip 10 is subjected to little or no stress when the cover plate 16 is attached to the conductive layer 14 under application of both heat and pressure. The chip 10 may, for example, comprise a transponder, and the conductive layer 14 the transponder aerial. Also described is a procedure for the manufacture of the encapsulated chip, which is suitable, for example, for the manufacture of flexible smart labels.

### FIELD OF THE INVENTION

The invention generally relates to an encapsulated chip and specifically to an encapsulated transponder chip in a smart label.

### BACKGROUND OF THE INVENTION

The cost of producing integrated circuits has fallen considerably in the past few years. As a consequence, a considerable range of new application fields has opened up for integrated circuits. Examples of this are the so-called smart labels for marking goods and for the identification of goods. Smart labels consist of a transponder chip in which the product-relevant information is stored, and an aerial to couple it to a reading device, which enables non-contact reading of the data stored in the transponder chip.

In the case of many smart labels, the transponder chip is built onto a base substrate that surrounds the aerial in the form of a conductive layer. The aerial is connected to the transponder chip. For these applications, the chips may be packed into a housing of, for example, plastic, or they may be directly built onto the base substrate, for example by means of flip-chip technology.

### SUMMARY OF THE INVENTION

The invention provides a new type of encapsulated chip, particularly suitable for smart label applications, which has a housing-that may be of flexible construction and which, at the same time, facilitates external contacting of the chip, and which can be produced by a simple and cost-effective process, whereby the chip is exposed to very little mechanical stress during the production process of the housing.

According to an embodiment of the invention, the chip is built onto a baseplate, on which the chip is located in such a way that its contact surfaces face away from the baseplate, where a layer of conductive material arranged around the chip is applied to the baseplate, which serves to connect the chip, is at least exactly as high as the chip, and functions as support for a cover plate arranged on the layer, one side of which, opposed to the chip, being provided with conductive surfaces that are arranged in such a way as to form a connection between the chip and the layer.

The chip according to and embodiment of the invention is of particularly simple construction that makes possible a cost-effective production process, consisting of only a few process steps, which is of particular importance when mass products, such as smart labels, are to be manufactured. The cover plate fulfils a dual function in this case. It allows the encapsulation of the chip and, at the same time, the establishment of electrical contact between the chip and the conductive layer that may consist, for example, of a transponder aerial. The chip is also mechanically stress-relieved in that the conductive layer is at least as high as the chip, or higher than the chip. This fact is particularly useful when the chip is integrated in a smart label.

The requirement of the invention is met, according to the invention, by several processes for the manufacture of encapsulated chips.

According to a first method for the manufacture of an encapsulated chip according to the invention, the chip is attached to a baseplate in such a way that its contact surfaces face away from the baseplate, and a conductive layer, that serves to connect the chip and that is at least as high as the chip, is applied around the chip onto the baseplate. Furthermore, a cover plate is provided where on one of its sides one or more conductive surfaces are arranged in such a way that they can form a connection between the chip and the layer. An anisotropically conductive film is then applied to one side of the cover plate and the cover plate is then aligned over the baseplate so that the side with the conductive surface or the conductive surfaces, respectively, is arranged over the chip so as to enable a connection between the chip and the layer to be formed. The cover plate is finally pressed onto the layer, under application of heat, in such a way that the anisotropically conductive film forms a mechanical and an electrical connection between the contact surfaces of the chip and the conductive surface or the conductive surfaces, respectively, of the cover plate and, at the same time, an electrical and a mechanical connection between the conductive surface or the conductive surfaces, respectively, of the cover plate and the layer.

According to a second method for the manufacture of an encapsulated chip according to the invention, a conductive layer which serves to connect the chip and that is at least as high as the chip itself, is applied to a baseplate around an area intended for the chip. Then one or more conductive surfaces are arranged on one side of a cover plate in such a way that they can form a connection between the chip and the layer, and an anisotropically conductive film is applied over the conductive film on one side of the cover plate. The chip is then positioned on the anisotropically conductive film so that its contact surfaces point towards the cover plate, and the cover plate is positioned on the baseplate in such a way that the chip comes to rest on the surface area intended for it and a connection between the chip and the layer can be formed. The cover plate is finally pressed onto the layer, under application of heat, in such a way that the anisotropically conductive film forms a mechanical and an electrical connection between the contact surfaces of the chip and the conductive surface or the conductive surfaces, respectively, of the cover plate and, at the same time, an electrical and a mechanical connection between the conductive surface or the conductive surfaces, respectively, of the cover plate and the layer.

### BRIEF DESCRIPTION OF THE DRAWINGS

Advantageous further developments of the invention are characterized in the sub-claims.

The invention shall now be explained in exemplified form with reference to the drawing, where

FIG. 1 represents a sectional side view of a first embodiment version of an encapsulated chip according to the invention,

FIG. 2 a plan view of a further embodiment version of a chip according to the invention,

FIGS. 3a to 3g sectional side views of the parts of an encapsulated chip produced during the individual manufacturing stages in a first procedure according to the invention for the production of an encapsulated chip, and

FIGS. 4a to 4g sectional side views of the parts of an encapsulated chip produced during the individual manufacturing stages in a second procedure according to the invention for the production of an encapsulated chip.

### DETAILED DESCRIPTION OF THE PRESENT INVENTION

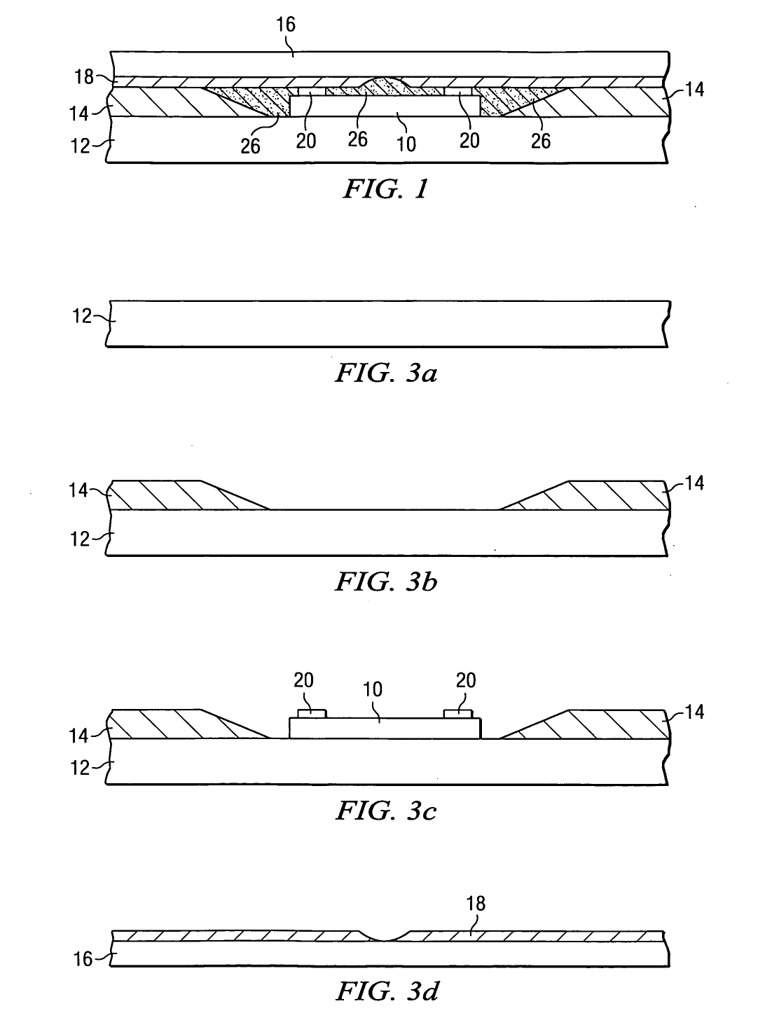

FIG. 1 shows an encapsulated chip according an embodiment of the invention. The chip 10 is attached to a baseplate 12 with its inactive back side. The baseplate 12 may consist of a rigid base material, for example an epoxy resin with glass fiber reinforcement, or it can be a flexible foil of, for example, polyethylene (PET) or polyamide. In order to achieve a flexible construction, the inactive back side of the chip 10 can be ground down to the extent that it becomes flexible. With a chip 10 consisting mostly of silicon, this flexibility can be achieved at a thickness of less than 50 μm.

An electrically conductive layer 14 that can consist of, for example, aluminum or copper, is applied to the baseplate 12. This layer 14 serves to connect the chip 10 to other component parts arranged on the baseplate 12, which are not represented in the FIG. 1. The electrically conductive layer 14 is applied around the chip 10, and is so high that it is at least as high or higher than the chip 10 together with its contact surfaces 20. If the chip 10 is made flexible by grinding it down, the layer 14 will be approximately 50 μm high. The layer 14 can consist, for example, of two narrow aluminum strips, which are arranged along two sides of a rectangular chip 10. It is not absolutely necessary for the layer 14 to surround the chip 10 completely. It is only important for the conductive layer 14 to be able to serve as a support for a cover plate 16. Conductive surfaces 18 are fitted to the cover plate 16, which, for example, can also consist of a flexible foil, and which provide an electrical contact between the conductive layer 14 on the baseplate 12 and the contact surfaces 20 of the chip 10. The conductive surfaces 18 can, for example, consist of glued-on thin aluminum or copper strips, or be printed on in the form of an electrically conductive lacquer (such as graphite lacquer).

The chip 10 is surrounded by filling material 26. This may consist, for example, of two different glues: A conductive glue that is applied to the contact surfaces 20 and which connects the conductive surfaces 18 of the cover plate 16 with the contact surfaces 20 of the chip 10, as well as a non-conductive glue that surrounds the chip 10. In order to establish an electrical connection between the contact surfaces 20 of the chip and the conductive surfaces 18 of the cover plate 16, an anisotropically conductive film (ACF) can also be used, that is a material that has a very low electrical resistance in only one direction whilst it is virtually non-conductive in the direction perpendicular to the other. The anisotropically conductive film 26 may consist, for example, of an epoxy resin containing a very large number of electrically conductive particles, which are-arranged so as to touch each other only along the direction in which electrical conductivity is desired. The epoxy resin also serves as the filling material that fully encloses the chip 10 and protects it from external influences, such as touch contact or humidity.

The conductive layer 14 on the baseplate 12 can be contact-bonded to the conductive surfaces 18 of the cover plate 16 by purely mechanical means, such as by crimping. The electrical connection can also be achieved by means of an electrically conductive glue or an anisotropically conductive film.

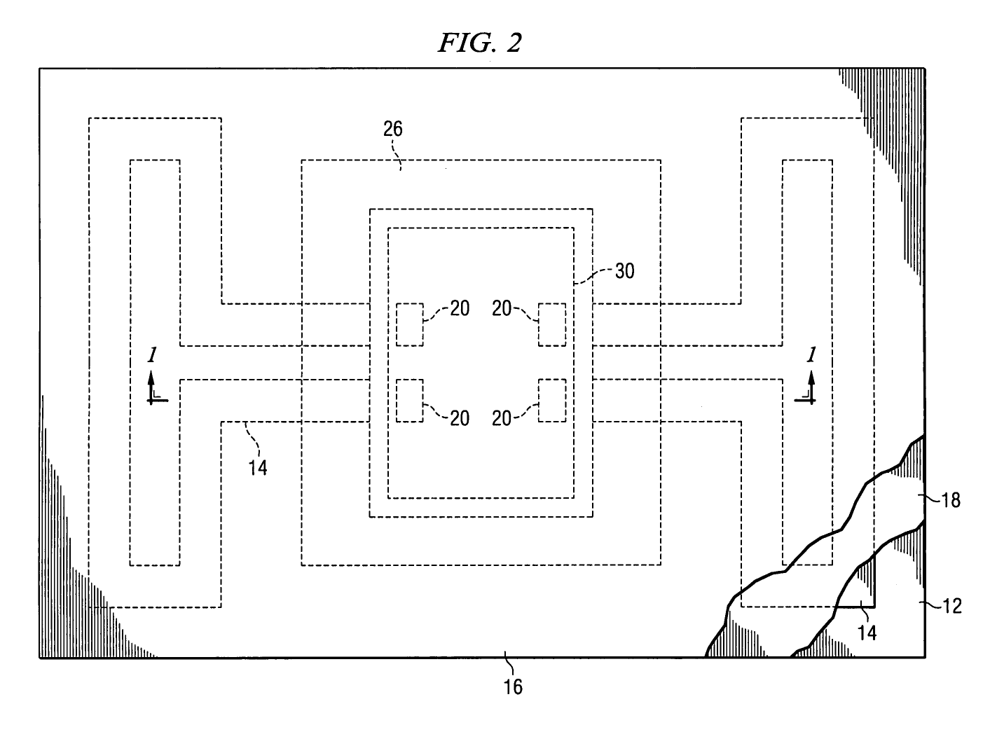

FIG. 2 shows the plan view of an embodiment version of the encapsulated chip according to the invention, where the conductive layer 14 on the baseplate 12 forms an aerial that is connected to a flexible transponder chip 30. The baseplate 12 may consist, for example, of a thin flexible PET foil, to which the aerial 14 of either copper or aluminum is attached. Conductive surfaces 18, of copper or aluminum, are arranged on the cover plate 16, which also consists of a thin flexible PET foil. An anisotropically conductive film 26 ensures the connection between the conductive layer 14 on the baseplate 12 and the contact surfaces 20 of the transponder chip 30.

The transponder chip 30, together with the aerial and the casing, can be embodied as a so-called smart label, where, for example, in the memory of the transponder chip 30, information is stored that represents the characteristics of an object to which the smart label is attached. Several of these smart labels may, for example, be attached to a paper strip, which then may be coiled up for compact transport and easy handling of the smart labels. In the case of these coiled rolls, which may contain thousands of coiled-up smart labels, enormous pressure is exerted on some of the individual smart labels and, in consequence, on the delicate transponder chips 30. The transponder chips 30 are well able to resist this pressure, since they are pressure-relieved by the conductive surfaces 14 that are as high or higher than the transponder chips 30, and occupy a relatively large surface area as compared with the transponder chip.

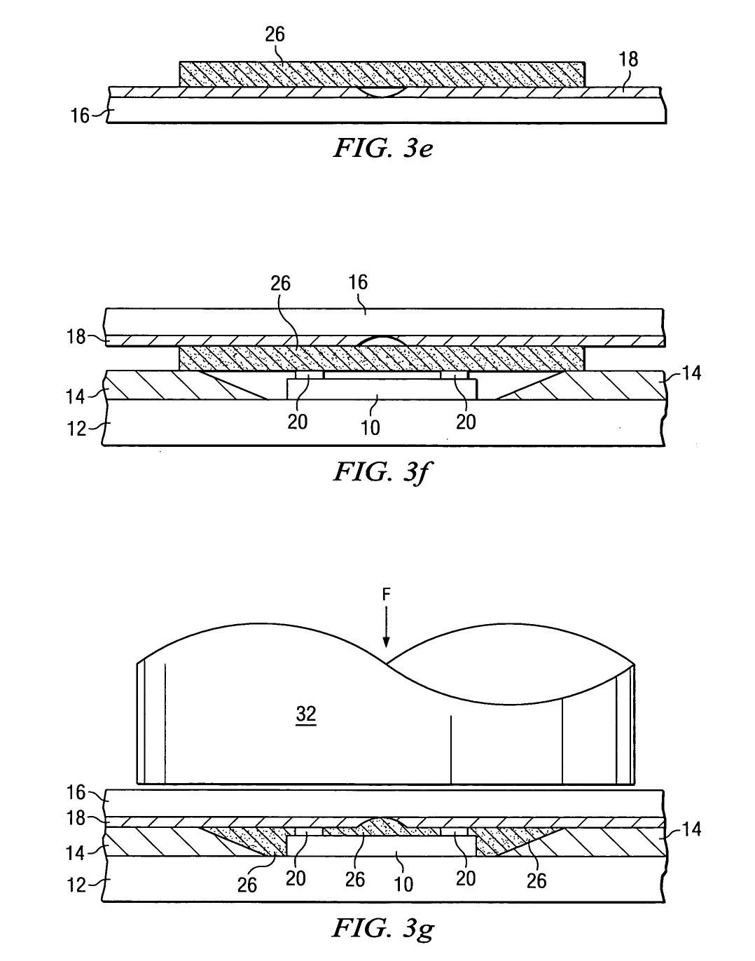

A procedure according to the invention for the manufacture of an encapsulated chip 10 shall be explained in the following, with reference to the FIGS. 3a to 3g. In a first step, which is represented in FIG. 3a, a baseplate 12 is provided. The baseplate 12 may consist of a rigid base substrate, such as an epoxy resin with glass fiber reinforcement, or it may be embodied as a flexible foil consisting of PET or polyamide.

As can be appreciated in FIG. 3b, a conductive layer 14 is then applied to the baseplate 12. The conductive layer 14 may consist of, for example, copper or aluminum, and is at least as high as the chip 10 that will be added later (see FIG. 3c). The conductive layer 14 is applied to the baseplate 12 around an area intended to accommodate the chip 10.

As represented in FIG. 3c, the chip 10 is attached to the intended surface on the baseplate 12 by means of, for example, glue bonding. In a fourth step, as represented in FIG. 3d, a cover plate 16 is provided, which may be made of the same material as the baseplate 12. Two conductive surfaces 18, consisting for example of aluminum or copper, and separated from each other by an insulating section, are applied to this cover plate 16.

As can be appreciated in FIG. 3e, the cover plate 16 is provided in a next step with an anisotropically conductive film 26, which is applied onto the conductive surfaces 18.

Then, as may be appreciated in FIG. 3f, the side of the conductive surfaces 18 of the cover plate 16 is positioned over the baseplate 12 so that a first conductive surface 18 can make connection to both a first part of the conductive layer 14, as well as to a first contact surface 20, as can be appreciated on the left hand of FIG. 3f, and a second conductive surface 18, that is isolated from the first conductive surface 18, can make connection to both a second part of the conductive layer 14, as well as to a second contact surface 20.

In the last step, as shown in FIG. 3g, the cover plate 16 is pressed onto the baseplate 10 by means of a piston ram 32, and under the application of heat. The anisotropically conductive film 26 thereby establishes an electrical connection between the contact surfaces 20 of the chip 10 and the conductive surfaces 18 on the cover plate 16, as well as between the conductive layer 14 on the baseplate 12 and the conductive surfaces 18 on the cover plate 16. As a result of the application of both heat and pressure, the anisotropically conductive film 26 spreads around the chip 10 and seals this hermetically.

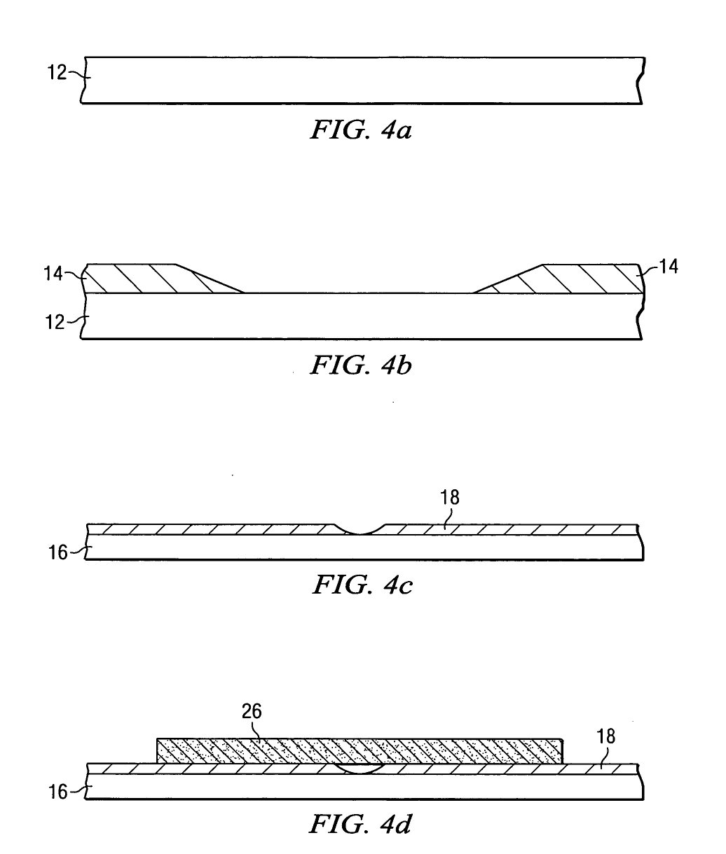

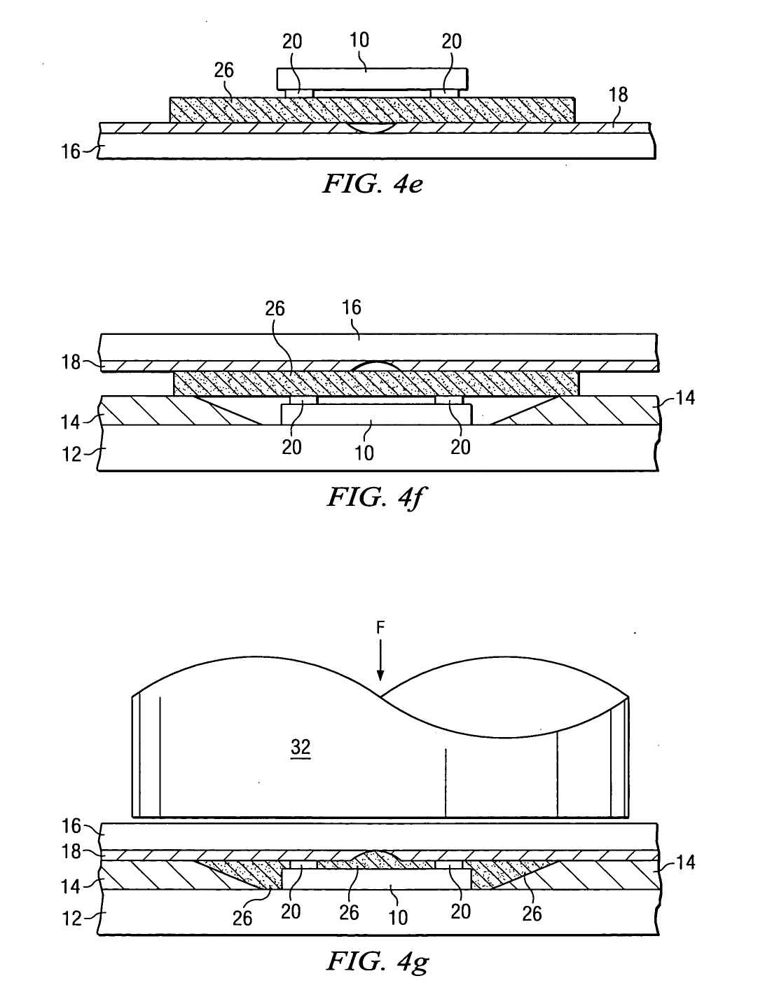

A second procedure according to the invention for the manufacture of an encapsulated chip is represented in the FIGS. 4a to 4g. In a first step, represented in FIG. 4a, a baseplate 12 is provided. The baseplate 12 may consist of a rigid base substrate, such as an epoxy resin with glass fiber reinforcement, or it may be embodied as a flexible foil consisting of PET or polyamide.

In a second step (FIG. 4b) a conductive layer 14 is then applied to the baseplate 12. The conductive layer 14 may consist of, for example, copper or aluminum, and is applied to the baseplate 12 around an area intended to accommodate the chip 10 (see FIG. 4f). The conductive layer 14 is at least as high as the chip 10.

In the next step (FIG. 4c), a cover plate 16 is provided that may be made of the same material as the baseplate 12. Areal conductive layers, made of aluminum or copper for example, are applied to this cover plate 16. Two conductive surfaces 18 that are isolated from each other are represented in FIG. 4c.

As represented in FIG. 4d, the cover plate 16 is then provided with an anisotropically conductive film 26, which is applied to the side of the cover plate 16 with its conductive surfaces 18.

Following this, as shown in FIG. 4e, the chip 10 is applied to the cover plate 16 so that its contact surfaces 20 face the conductive surfaces 18, and an electrical connection can be established in the desired way between some of the contact surfaces 20 of the chip 10 and specific conductive surfaces 18.

Then, as may be appreciated in FIG. 4f, the side of the cover plate 16 with the conductive surfaces 18 is positioned over the baseplate 12 so that parts of the conductive surfaces 18 can establish electrical connections to parts of the layer 14. The chip 10 is hereby positioned in a way that allows it to be surrounded by the conductive layer 14 on the baseplate 12.

In the last step, as shown in FIG. 4g, the cover plate 16 is pressed onto the baseplate 12 by means of a piston ram 32, and under the application of heat, as in the first step described above.

Procedures for the manufacture of an encapsulated chip 10, which may be modified in a plurality of ways, have been described by giving two concrete examples. The anisotropically conductive film 26 may be applied, for example, to only a smaller surface, whereby the conductive layer 14 and parts of the conductive surfaces 18 will not be covered. Then, before pressing the cover plate 16 onto the baseplate 12, the conductive layer 14 on the baseplate 12 and the conductive surfaces 18 on the cover plate 16 can be connected by crimping. The crimping connection can be achieved, for example, by a mechanical deformation process or by means of ultrasound. The connection can, of course, also be made by means of the anisotropically conductive film.

1. An encapsulated chip assembly comprising:
a baseplate (12),
a chip (10) attached to the baseplate in such a way that its contact surfaces (20) face away from the baseplate (12),
a layer (14) of a conductive material applied to the baseplate (12) and arranged to around the chip (10), and which is at least as high as the chip (10),
a cover plate (16) arranged on the layer of conductive material (14), whose one side, opposing the chip (10), being provided with one or more conductive surfaces (18), which are arranged in such a way that they form an electrical connection between the chip (10) and the layer of conductive material (14).

2. The encapsulated chip according to claim 1, whereby the chip (10) is surrounded by a filler material that fills the open space between the baseplate (12) and the cover plate (16).

3. The encapsulated chip according to claim 2, further comprising an electrically conductive glue, which is to establish both the electrical and the mechanical connections between the contact surfaces (20) of the chip (10) and the conductive surface (18) or the conductive surfaces (18), respectively, of the cover plate (16).

4. The encapsulated chip according to claim 2, further comprising an anisotropically conductive film (26) (ACF), which serves to establish both an electrical and a mechanical connection between the contact surfaces (20) of the chip (10) and the conductive surface (18) or the conductive surfaces (18), respectively, of the cover plate (16), and between the conductive surface (18) or the conductive surfaces (18), respectively, of the cover plate (16) and the conductive layer (14) applied to the baseplate (12).

5. The encapsulated chip according to claim 4, whereby the filler material consists of the anisotropically conductive film (26).

6. The encapsulated chip according to claim 1, where both the baseplate (12) and the cover plate (16) each consist of a flexible material.

7. The encapsulated chip according to claim 1, where the height of the chip (10) is so low that it is rendered flexible.

8. The encapsulated chip according to claim 7, where the chip (10) consists mainly of silicon and has a thickness of less than 50 im.

9. The encapsulated chip according to claim 1, where the chip (10) comprises a transponder.

10. The encapsulated chip according to claim 9, where the conductive layer (14) comprises an aerial.

11. An encapsulated chip assembly for a smart label comprising:
a flexible baseplate (12),
a chip (10) having a transponder attached to the baseplate in such a way that its contact surfaces (20) face away from the baseplate (12),
a layer (14) of a conductive material applied to the baseplate (12) and arranged to around the chip (10), and which is at least as high as the chip (10) and forms an aerial for electrical signals for the transponder,
a cover plate (16) arranged on the layer of conductive material (14), whose one side, opposing the chip (10), being provided with one or more conductive surfaces (18), which are arranged in such a way that they form an electrical connection between the chip (10) and the layer of conductive material (14).

12. The encapsulated chip according to claim 11, further comprising an electrically conductive glue, which is to establish both the electrical and the mechanical connections between the contact surfaces (20) of the chip (10) and the conductive surface (18) or the conductive surfaces (18), respectively, of the cover plate (16).

13. The encapsulated chip according to claim 12, further comprising an anisotropically conductive film (26) (ACF), which serves to establish both an electrical and a mechanical connection between the contact surfaces (20) of the chip (10) and the conductive surface (18) or the conductive surfaces (18), respectively, of the cover plate (16), and between the conductive surface (18) or the conductive surfaces (18), respectively, of the cover plate (16) and the conductive layer (14) applied to the baseplate (12).

14. The encapsulated chip according to claim 11, where the height of the chip (10) is so low that it is rendered flexible.

15. The encapsulated chip according to claim 14, where the chip (10) consists mainly of silicon and has a thickness of less than 50 μm.

16. Method for the manufacture of encapsulated chips, where the steps comprise:
the chip (10) is attached to a baseplate (12) in such a way that its contact surfaces (20) face away from the baseplate (12), and where a conductive layer (14) that serves to connect the chip (10) and is at least as high as the chip (10), is applied to the baseplate (12) to surround the chip (10),
a cover plate (16) is provided on whose one side one or more conductive surfaces (18) are arranged so that they can establish a connection between the chip (10) and the layer (14),
an anisotropically conductive film (26) is applied to the one side of the cover plate (16),
the cover plate (16) is aligned over the baseplate (12) so that the side with the conductive surface (18) or the conductive surfaces (18), respectively, is positioned over the chip (10) so that a connection between the chip (10) and the layer (14) can be established,
the cover plate (16) is pressed onto the layer (14), under the application of heat, so that the anisotropically conductive film (26) establishes both a mechanical and an electrical connection between the contact surfaces (20) of the chip (10) and the conductive surface (18) or the conductive surfaces (18), respectively, of the cover plate (16), and that at the same time an electrical and a mechanical connection is established between the conductive surface (18) or the conductive surfaces (18), respectively, and the layer (14).

17. Method for the manufacture of an encapsulated chip, whereby
a conductive layer (14), serving to connect a chip (10), that is at least as high as the chip (10), is applied to a baseplate around an area intended for the chip (10),
on one side of a cover plate (16) one or more conductive surfaces (18) are arranged in such a way as to be able to form a connection between the chip (10) and the layer (14),
an anisotropically conductive film (26) is applied to the one side of the cover plate (16) over the conductive surface (18) or the conductive surfaces (18), respectively,
the chip (10) is positioned on the anisotropically conductive film (26) in such a way that its contact surfaces (20) are facing the cover plate (16),
the cover plate (16) is placed onto the baseplate (12) in such a way that the chip (10) comes to rest on the surface area intended for it, and a connection between the chip (10) and the layer (14) can be established, and
where the cover plate (16) is pressed, under the application of heat, onto the layer (14) so that the anisotropically conductive film (26) forms both a mechanical and an electrical connection between the contact surfaces (20) of the chip (10) and the conductive surface (18) or the conductive surfaces (18), respectively, of the cover plate (16), and where at the same time an electrical and a mechanical connection between the conductive surface (18) or the conductive surfaces (18), respectively, of the cover plate (16) and the layer (14) is established.

18. Method according to claim 17, where the simultaneous connection between the conductive surface (18) or the conductive surfaces (18), respectively, of the cover plate (16) and the layer (14) is achieved by means of a crimping process.

19. Method according to claim 18, where the simultaneous connection between the conductive surface (18) or the conductive surfaces (18), respectively, of the cover plate (16) and the layer (14) is achieved by means of a crimping process.

20. Method according to claim 17, where the simultaneous connection between the conductive surface (18) or the conductive surfaces (18) of the cover plate (16) and the layer (14) is established by means of an anisotropically conductive film.
